(19) United States
(12) Patent Application Publication
(10) Pub. No.: US 2026/0319745 A1
(43) Pub. Date: Oct. 15, 2026

(54) SEMICONDUCTOR DEVICE

(71) Applicant: Renesas Electronics Corporation, Tokyo (JP)

(72) Inventors: Junichi SUZUKI, Tokyo (JP); Takashi ITO, Tokyo (JP); Hirokazu NAGASE, Tokyo (JP); Toshio UEMATSU, Tokyo (JP)

(21) Appl. No.: 19/556,707

(22) Filed: Mar. 4, 2026

(30) Foreign Application Priority Data
Apr. 14, 2025 (JP) 2025-066068

(51) Int. Cl. G06F 7/544; G11C 27/00

(52) U.S. Cl. CPC G06F 7/5443; G11C 27/005

(57) ABSTRACT

A semiconductor device includes memory cells connected to bit lines and to word lines, a determination circuit, and a row decoder to which input data corresponding to the word lines are supplied and which supplies, to the corresponding word lines, selection signals each having an input time width obtained by adding an offset pulse width to an effective pulse width corresponding to a value of the input data. The memory cells discharge charge amounts determined by stored data stored therein and the input time width, and the determination circuit determines a difference between charge amounts discharged by the memory cells and charge amounts based on the offset pulse width as a product of the value of the input data and the stored data, and outputs the result as a multiply-accumulate operation of the memory cells.

### CROSS-REFERENCE TO RELATED APPLICATIONS

The disclosure of Japanese Patent Application No. 2025-066068 filed on Apr. 14, 2025 including the specification, drawings and abstract is incorporated herein by reference in its entirety.

### BACKGROUND

The present invention relates to a semiconductor device, and more particularly to a semiconductor device including memory cells that perform a multiplication operation between stored data and input data.

There are disclosed techniques listed below.

### [Patent Document 1] Japanese Unexamined Patent Application Publication No. 2023-124082

Semiconductor devices such as processors equipped with Artificial Intelligence (AI) accelerators having a multiply-accumulate function have been developed for machine learning with a large processing volume. As a configuration for implementing the multiply-accumulate function, the use of Computing-In-Memory (CIM), which enables low power consumption and a reduced area, has been studied. An example of such a CIM is described in Patent Document 1.

### SUMMARY

The inventors studied the use of a configuration different from that described in Patent Document 1 as a CIM in order to achieve further area reduction.

In the CIM studied by the inventors, of two pieces of data subject to a multiplication operation, one piece of data (stored data) is stored in memory cells constituting a memory cell array, and the other piece of data (input data) is converted into time-length data and supplied as a selection signal to word lines of the memory cells. As a result, the memory cells discharge a charge amount determined by a product of the stored data and the time length of the input data, thereby making it possible to implement a multiplication operation.

However, as a result of studies conducted by the inventors, although this will be described in detail later using a comparative example, it has been found that there exists a problem in that an increase in processing speed is limited.

A brief overview of representative embodiments is as follows.

Specifically, a semiconductor device according to one embodiment includes a plurality of first memory cells connected to a first bit line and a plurality of first word lines, a determination circuit connected to the first bit line, and an input circuit to which input data corresponding to the first word lines are supplied and which supplies, to the corresponding first word lines, selection signals each having an input time width obtained by adding an offset pulse width having a predetermined time width to an effective pulse width having a time width corresponding to a value of the input data. The first memory cells discharge charge amounts determined by stored data stored therein and the input time width, and the determination circuit determines a difference between charge amounts discharged by the first memory cells and charge amounts based on the offset pulse width as a product of the value of the input data and the stored data, and outputs the result as a multiply-accumulate operation of the plurality of first memory cells.

Other objects and novel features will become apparent from the description of this specification and the accompanying drawings.

According to one embodiment, it is possible to provide a semiconductor device capable of achieving higher speed.

### BRIEF DESCRIPTION OF THE DRAWINGS

FIG. 1 is a block diagram illustrating a configuration of a semiconductor device according to a first embodiment.

FIG. 2 is a block diagram illustrating a configuration of an AI MAC arithmetic unit according to the first embodiment.

FIG. 3 is a circuit diagram illustrating an example of a memory cell array according to the first embodiment.

FIG. 4 is a diagram for explaining an example of use of the AI MAC arithmetic unit according to the first embodiment.

FIG. 5 is a block diagram illustrating a configuration of a row decoder according to the first embodiment.

FIG. 6A is a diagram for explaining an operation of the AI MAC arithmetic unit according to the first embodiment.

FIG. 6B is a diagram for explaining the operation of the AI MAC arithmetic unit according to the first embodiment.

FIG. 7A is a diagram for explaining the AI MAC arithmetic unit according to the first embodiment.

FIG. 7B is a diagram for explaining the AI MAC arithmetic unit according to the first embodiment.

FIG. 7C is a diagram for explaining the AI MAC arithmetic unit according to the first embodiment.

FIG. 7D is a diagram for explaining the AI MAC arithmetic unit according to the first embodiment.

FIG. 8A is a diagram for explaining the AI MAC arithmetic unit according to the first embodiment.

FIG. 8B is a diagram for explaining the AI MAC arithmetic unit according to the first embodiment.

FIG. 9 is a circuit diagram illustrating a configuration of the AI MAC arithmetic unit according to the first embodiment.

FIG. 10 is a waveform diagram for explaining an operation of the AI MAC arithmetic unit illustrated in FIG. 9.

FIG. 11 is a circuit diagram illustrating a configuration of an AI MAC arithmetic unit according to a modification of the first embodiment.

FIG. 12A is a diagram for explaining the operation of the AI MAC arithmetic unit illustrated in FIG. 11.

FIG. 12B is a diagram for explaining the operation of the AI MAC arithmetic unit illustrated in FIG. 11.

FIG. 12C is a diagram for explaining the operation of the AI MAC arithmetic unit illustrated in FIG. 11.

FIG. 12D is a diagram for explaining the operation of the AI MAC arithmetic unit illustrated in FIG. 11.

FIG. 13 is a circuit diagram illustrating a configuration of an AI MAC arithmetic unit according to a second embodiment.

FIG. 14A is a diagram for explaining an operation of the AI MAC arithmetic unit according to the second embodiment.

FIG. 14B is a diagram for explaining an operation of the AI MAC arithmetic unit according to the second embodiment.

FIG. 15 is a circuit diagram for explaining a CIM studied by the inventors.

FIG. 16 is a waveform diagram for explaining the CIM studied by the inventors.

FIG. 17A is a waveform diagram for explaining a problem found by the inventors.

FIG. 17B is a waveform diagram for explaining a problem found by the inventors.

FIG. 18 is a diagram for explaining a further problem found by the inventors.

### DETAILED DESCRIPTION

Hereinafter, embodiments of the present invention will be described with reference to the drawings. It should be noted that the disclosure is merely an example, and it is to be understood that any modifications that can be easily conceived by a person skilled in the art while maintaining the spirit of the invention are naturally included within the scope of the present invention.

In addition, in the present specification and the drawings, components similar to those previously described with reference to earlier drawings are denoted by the same reference numerals, and detailed descriptions thereof may be omitted as appropriate.

### Comparative Example

### Configuration and Operation of CIM

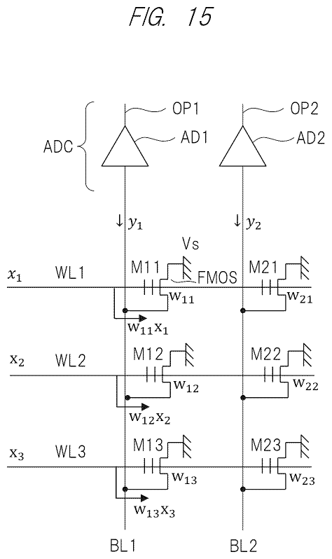

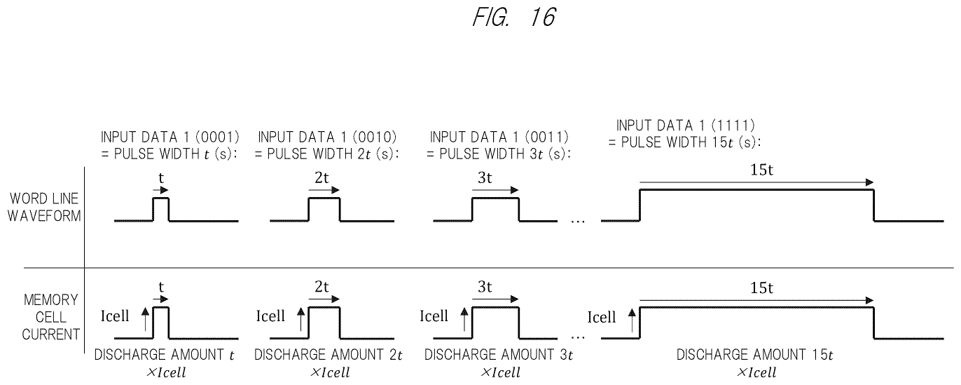

In order to facilitate understanding of the semiconductor device according to the embodiments, a CIM studied by the inventors will first be described. FIG. 15 is a circuit diagram for explaining the CIM studied by the inventors, and FIG. 16 is a waveform diagram for explaining the operation of the CIM studied by the inventors.

In FIG. 15, a main part of a memory cell array constituting the CIM is illustrated. In FIG. 15, M11 to M23 indicate memory cells arranged in a matrix in the memory cell array. In the memory cell array, the memory cells M11 to M13 (M21 to M23) arranged in the same column are connected to a bit line BL1 (BL2) arranged in the corresponding column. In addition, in the memory cell array, the memory cells M11 and M21 (M12 and M22, and M13 and M23) arranged in the same row are connected to a word line WL1 (WL2 and WL3) arranged in the corresponding row. The bit lines BL1 and BL2 are connected to analog-to-digital conversion circuits (hereinafter also referred to as AD conversion circuits or ADCs) AD1 and AD2. The bit lines BL1 and BL2 are precharged to a predetermined voltage before reading out data from the memory cells.

The memory cells M11 to M23 are not particularly limited, but in the example illustrated in FIG. 15, each memory cell is constituted by a flash memory cell including a field-effect transistor FMOS having a floating gate and a selection gate. The selection gate of the field-effect transistor FMOS is connected to a corresponding word line (for example, WL1), a source thereof is connected to a ground voltage Vs, and a drain thereof is connected to a corresponding bit line (for example, BL1). Data is written in advance to the field-effect transistor FMOS. The written data is stored in a memory cell (for example, M11) as stored data. In FIG. 15, data stored in the memory cells M11 to M23 is denoted by symbols w₁₁ to w₂₃. In addition, selection signals x₁ to x₃ having time lengths (time widths) corresponding to input data are supplied to the word lines WL1 to WL3.

FIG. 16 illustrates a case in which input data 1 is 4-bit parallel data (four numerical values of “1” and “0” in parentheses). The 4-bit parallel data is converted into a selection signal having a corresponding time length. For example, input data 1 having a value of 1 (0001 ) is converted into a selection signal having a predetermined time length t (s). As illustrated in FIG. 16, the selection signal is a signal that sets the word line to a high level. The predetermined time length t(s) corresponding to input data 1 is defined as a unit time, and the time length (pulse width) of the selection signal increases in units of the unit time according to the value of input data 1. For example, as illustrated in FIG. 16, when the values are 2 (0010), 3 (0011), and 15 (1111), the pulse widths of the selection signal are 2t(s), 3t(s), and 15t(s), respectively. Although not illustrated in FIG. 16, when the value is 0(0000 ), input data 1 has no selection signal that sets the word line to a high level.

When the word line is set to a high level by the selection signal, during a high-level period of the selection signal, the field-effect transistor FMOS constituting the memory cell becomes conductive with an impedance value determined by the stored data stored therein. As a result, during the period of the selection signal, a memory cell current Icell flows from the bit line (for example, the bit line BL1) toward the ground voltage Vs. Specifically, the discharged amount (charge amount) that is to be discharged is given by a product of the period of the selection signal and the memory cell current Icell.

For example, for input data 1 having a value of 1, as illustrated in FIG. 16, the discharge amount is given by unit time t(s)×the memory cell current Icell. For input data 1 having a value of 2, the discharge amount is given by 2t(s)×the memory cell current Icell. For input data 1 having a value of 15, the discharge amount is given by 15t(s)×the memory cell current Icell. Of course, the value of the memory cell current Icell is determined according to the stored data.

The memory cells M11 to M13 illustrated in FIG. 15 become conductive with impedance values determined by the stored data w₁₁ to w₂₃ for time lengths specified by the selection signals x₁ to x₃. As a result, for example, the memory cell M11 discharges a charge amount determined by a product w₁₁x₁ of the stored data w₁₁ and the input data x₁. In the memory cells M12 and M13 as well, discharge is performed in the same manner as in the memory cell M11.

As a result, the charge of the bit line BL1 that has been precharged in advance is reduced by discharge of the memory cells M11 to M13, and a charge amount y1 determined by a multiply-accumulate operation (w₁₁x₁+w₁₂x₂+w₁₃x₃) is discharged. Accordingly, a result of the multiply-accumulate operation is output as a digital signal OP1 from the AD conversion circuit AD1.

According to the configuration illustrated in FIG. 15, it is possible to achieve a reduction in area of a CIM that performs a multiply-accumulate operation.

### Problems Found by the Inventors

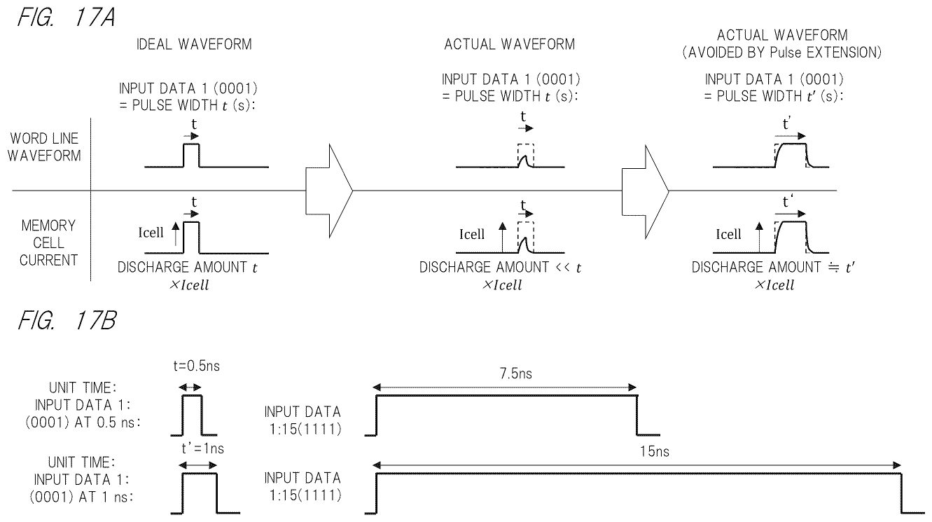

FIG. 17 is a waveform diagram for explaining problems found by the inventors.

Parasitic capacitance and parasitic impedance are associated with wiring such as the word lines. Due to the parasitic capacitance and the parasitic impedance, a parasitic delay circuit is formed, and a waveform on the word line deviates from an ideal waveform.

When a period of a selection signal that sets the word line to a high level is too short, a phenomenon occurs in which a voltage of the word line does not fully rise due to a parasitic delay circuit. Since the period of the selection signal is shortest when a value of input data 1 corresponding to the unit time is 1(0001 ), a case where the value is 1 will be described as an example.

In FIG. 17A, a word line waveform and a memory cell current illustrated as ideal waveforms are the same as those illustrated in FIG. 16. In FIG. 17A, a word line waveform illustrated as an actual waveform indicates a state in which the word line does not fully rise due to the parasitic delay circuit. A period during which the word line waveform rises is short, and a value thereof is also small. Therefore, a discharge amount of the memory cell current is reduced as compared with an ideal discharge amount t×Icell. As a result, it is conceivable that a result of the multiply-accumulate operation becomes incorrect.

This problem can be avoided by increasing the unit time, specifically, by extending a pulse width of the value 1 (0001 ). By changing the pulse width of the selection signal for the value 1 from t to t′, as illustrated by an actual waveform (avoided by pulse extension) illustrated on a right side of the drawing in FIG. 17A, the word line waveform fully rises although transient variations are present. As a result, a discharge amount of the memory cell current becomes t′×Icell after extension, making it possible to prevent the multiply-accumulate operation result from becoming incorrect.

However, when the pulse width is extended, the speed is limited. For example, FIG. 17B illustrates a word line waveform in a case where the unit time t(s), which was 0.5 ns, is extended to 1 ns, and a value of input data 1 is 15 (1111 ). As illustrated in FIG. 17B, when the unit time is 0.5 ns, a pulse width during which the word line waveform is at a high level is 7.5 ns, whereas when the unit time is 1 ns, the pulse width of the word line waveform is doubled to 15 ns. Since a period during which the memory cell current is discharged becomes longer, the speed is limited. In addition, power consumption also increases. Here, a case in which input data 1 is 4-bit data has been described; however, when input data is n-bit data, the pulse width becomes a maximum of 2ⁿ times.

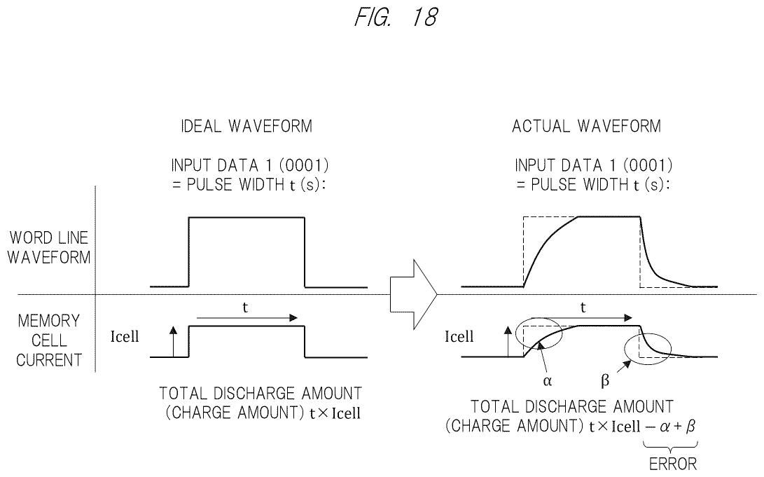

FIG. 18 is a diagram for explaining a further problem found by the inventors. In FIG. 18, as illustrated as an ideal waveform, it is ideal that rising and falling edges of the word line and rising and falling edges of the memory cell current generated accordingly are vertical. However, in an actual waveform, as illustrated in FIG. 18, transient variations are present at the rising and falling edges. Due to the transient variations, errors α and β occur with respect to the ideal waveform. These errors are accumulated by a number of memory cells connected to the same bit line. For example, when the number of memory cells connected to the same bit line is 128, an error that reaches the AD conversion circuit becomes a maximum of 128 times.

### First Embodiment

### Overall Configuration of Semiconductor Device

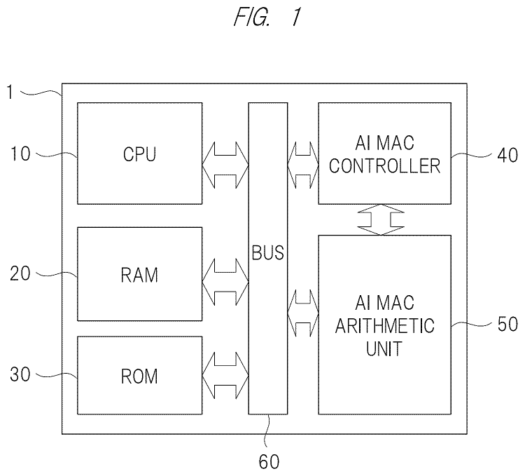

FIG. 1 is a block diagram illustrating a configuration of a semiconductor device according to a first embodiment. In FIG. 1, reference numeral 1 denotes the semiconductor device. The semiconductor device 1 is not particularly limited, but includes a processor 10, a volatile memory (RAM) 20, a nonvolatile memory (ROM) 30, an AI Multiply-Accumulate (MAC) arithmetic unit 50, an AI MAC controller 40 that controls the AI MAC arithmetic unit 50, and an internal bus 60.

As illustrated in FIG. 1, the processor 10, the RAM 20, the ROM 30, the AI MAC arithmetic unit 50, and the AI MAC controller 40 are connected by the internal bus 60. When the processor 10 operates according to a program stored in the ROM 30, predetermined functions are implemented in the semiconductor device 1. When implementing the predetermined functions, the RAM 20 is used, for example, to temporarily store data.

In the semiconductor device 1 according to the first embodiment, an AI accelerator is constituted by the AI MAC controller 40 and the AI MAC arithmetic unit 50. In the first embodiment, the AI MAC arithmetic unit 50 is implemented by a CIM.

When AI processing such as an inference operation is implemented in the semiconductor device 1, for example, the processor 10 supplies input data for the inference operation to the AI MAC arithmetic unit 50 via the internal bus 60 and receives operation results of the AI MAC arithmetic unit 50 via the internal bus 60. In one example, the processor 10 controls the AI MAC arithmetic unit 50 via the AI MAC controller 40 such that the AI MAC arithmetic unit 50 performs desired arithmetic processing.

### AI MAC Arithmetic Unit

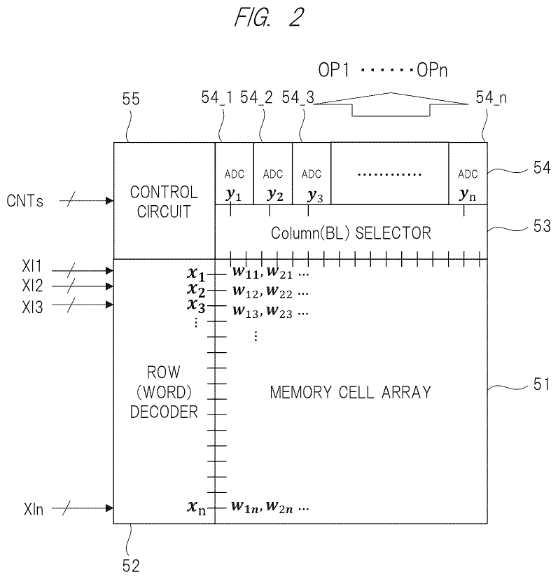

FIG. 2 is a block diagram illustrating a configuration of the AI MAC arithmetic unit according to the first embodiment. The AI MAC arithmetic unit 50 illustrated in FIG. 1 is constituted by a plurality of circuit blocks; however, FIG. 2 illustrates only circuit blocks necessary for explanation.

Since the AI MAC arithmetic unit 50 is implemented by a CIM, the AI MAC arithmetic unit 50 is implemented with a configuration similar to that of a memory. The AI MAC arithmetic unit 50 includes a memory cell array 51, a row decoder 52, a column selector 53, an AD conversion circuit 54, and a control circuit 55.

The memory cell array 51 includes a plurality of memory cells arranged in a matrix, word lines arranged in respective rows and connected to the memory cells in corresponding rows, and bit lines arranged in respective columns and connected to the memory cells arranged in corresponding columns.

The row decoder (hereinafter also referred to as an input circuit) 52 is connected to the plurality of word lines arranged in the memory cell array 51 and to the internal bus 60 illustrated in FIG. 1. In one example, the row decoder 52 receives input data XI1 to XIn from the internal bus 60 and supplies selection signals (hereinafter referred to as input data) x₁ to xₙ corresponding to the input data XI1 to XIn to word lines corresponding to the input data XI1 to XIn. Each of the input data XI1 to XIn is composed of a plurality of parallel bits, and the row decoder 52 converts parallel-bit input data (for example, XI1) into serial input data, specifically, input data having a corresponding time length (for example, the selection signal x1).

The column selector 53 is connected to the plurality of bit lines arranged in the memory cell array 51 and to the AD conversion circuit 54. The AD conversion circuit 54 is constituted by a plurality of unit AD conversion circuits 54_1 to 54_n corresponding to the plurality of bit lines arranged in the memory cell array 51. During a readout operation, the column selector 53 connects bit lines arranged in the memory cell array 51 to corresponding unit AD conversion circuits. As a result, a voltage on each bit line (determined by charge amounts y₁ to yₙ), is supplied to the corresponding unit AD conversion circuit.

The AD conversion circuit 54 supplies signals from the column selector 53 to the internal bus 60 (FIG. 1) as digital signals OP1 to OPn. The control circuit 55 generates various control signals for controlling the inside of the AI MAC arithmetic unit 50 based on control signals CNTs from the AI MAC controller 40 (FIG. 1).

### Configuration of Memory Cell Array

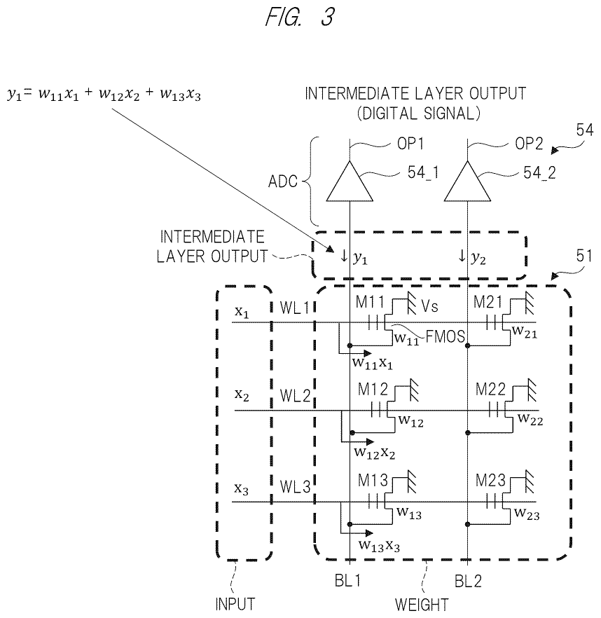

FIG. 3 is a circuit diagram illustrating an example of the memory cell array according to the first embodiment. FIG. 3 is similar to FIG. 15, and FIG. 3 illustrates, as an example, a matrix portion of two rows and two columns in the memory cell array 51 illustrated in FIG. 2. In FIG. 3, the unit AD conversion circuits 54_1 and 54_2 are illustrated as examples; however, the column selector 53 (FIG. 2) is omitted.

A main difference between FIG. 3 and FIG. 15 is that reference numerals 51, 54, 54_1, and 54_2 are added in FIG. 3 to indicate correspondence with components illustrated in FIG. 2. In addition, FIG. 3 is different in that names of functional blocks (such as weights) in a multilayer perceptron structure used for machine learning and multiply-accumulate expressions are explicitly illustrated. Other than the above, FIG. 3 is the same as FIG. 15, and therefore a detailed description thereof is omitted.

### Example of Use of AI MAC Arithmetic Unit

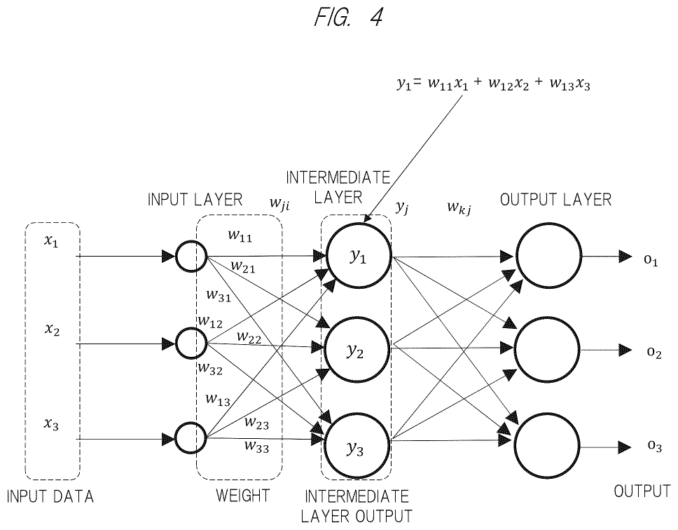

Here, an example of use of the AI MAC arithmetic unit according to the first embodiment will be described. In this example, a case in which the AI MAC arithmetic unit is used for machine learning will be described. Of course, the present invention is not limited to this example of use. FIG. 4 is a diagram for explaining an example of use of the AI MAC arithmetic unit according to the first embodiment. FIG. 4 illustrates a neural network having a multilayer perceptron structure used for machine learning.

As illustrated in FIG. 4, the neural network includes an input layer, an intermediate layer, and an output layer. In the input layer, products of input data x₁ to x₃ and weight data w₁₁ to w₃₃ (for example, w₁₁x₁, w₁₂x₂, and w₁₃x₃) are obtained, and in the intermediate layer, sums of the products of the input data and the weight data are obtained. Specifically, a multiply-accumulate operation of the input data and the weight data (for example, w₁₁x₁+w₁₂x₂+w₁₃x₃) is performed in the input layer and the intermediate layer. A result of the multiply-accumulate operation is supplied to the output layer and becomes outputs o₁ to o₃.

The memory cells (first memory cells) M11 to M23 in the memory cell array 51 illustrated in FIG. 3 are written in advance with weight data w₁₁ to w₂₃. As a result, the weight data w₁₁ to w₂₃ are stored as stored data in the memory cells M11 to M23. When the input data x₁ to x₃ are supplied to the word lines (first word lines) WL1 to WL3, for example, the memory cells M11 to M13 connected to the bit line (first bit line) BL1 become conductive with impedances determined by the stored data (weight data) w₁₁ to w₁₃ for periods determined by the input data x₁ to x₃. As a result, a voltage of the bit line BL1 becomes a voltage determined by a charge amount y₁=w₁₁x₁+w₁₂x₂+w₁₃x₃. Specifically, the voltage of the bit line BL1 becomes an output of the intermediate layer, as illustrated in FIGS. 3 and 4. As illustrated in FIG. 3, the output of the intermediate layer is converted into a digital signal and supplied to the output layer illustrated in FIG. 4.

According to the AI MAC arithmetic unit illustrated in FIG. 4, it is possible to obtain results of a plurality of multiply-accumulate operations substantially simultaneously from each of a plurality of bit lines (for example, the bit lines BL1 and BL2 illustrated in FIG. 3).

### Row Decoder (Input Circuit)

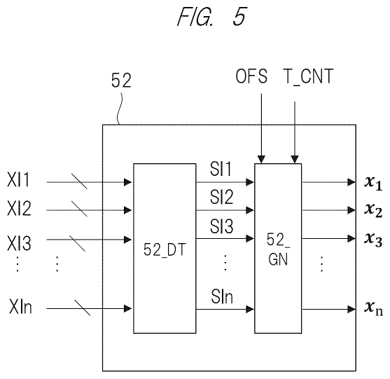

FIG. 5 is a block diagram illustrating a configuration of the row decoder according to the first embodiment. In one example, the row decoder 52 according to the first embodiment includes a digital-to-time-length (pulse width) conversion circuit (hereinafter also referred to as a DT conversion circuit) 52_DT and a selection signal generation circuit 52_GN.

The DT conversion circuit 52_DT receives, from the internal bus 60, input data XI1 to XIn each composed of a plurality of parallel bits. The DT conversion circuit 52_DT converts the supplied input data XI1 to XIn into serial signals SI1 to SIn each having a time length (pulse width) corresponding to a value represented by the parallel bits of the input data XI1 to XIn. For example, when each of the input data XI1 to XIn is a parallel 4-bit digital signal, the DT conversion circuit 52_DT converts the input data into serial signals SI1 to SIn each having a high level for a time length corresponding to a value represented by the 4-bit digital signal. Taking the input data XI1 as an example, since the input data XI1 is 4-bit parallel data, a value represented by the input data XI1 is one of values from 0 to 15. The DT conversion circuit 52_DT converts the input data XI1 into the serial signal SI1 having one of time lengths corresponding to values from 0 to 15. Here, a time length (pulse width) IN₁ corresponding to the value 1 is defined as a predetermined minimum unit time length (hereinafter also referred to as a minimum unit). Time lengths (pulse widths) corresponding to values from 2 to 15 are time lengths IN₂ to IN₁₅ that are 2 to 15 times the minimum unit IN₁ (a time length or pulse width INᵢ where i represents a value of 1 to 15 of the input data XI).

The selection signal generation circuit 52_GN is supplied with serial signals SI1 to SIn, an offset pulse signal OFS having a predetermined offset pulse width IN_{ofs}, and a timing signal T_CNT that specifies a first period or a second period. In one example, the offset pulse signal OFS and the timing signal T_CNT are supplied from the control circuit 55 illustrated in FIG. 2.

The selection signal generation circuit 52_GN performs the same operation for any of the serial signals SI1 to SIn. Therefore, an operation of the selection signal generation circuit 52_GN will be described using the serial signal SI1 as a representative example. When the serial signal SI1 is a signal having a time length corresponding to any one of values 1 to 15 and the timing signal T_CNT specifies the first period, the selection signal generation circuit 52_GN outputs the offset pulse signal OFS as a selection signal. As a result, in the first period, a selection signal having the offset pulse width IN_{ofs} is supplied to the word line WL1 as the input data x₁.

On the other hand, when the serial signal SI1 is a signal having a time length corresponding to any one of values 1 to 15 and the timing signal T_CNT specifies the second period different from the first period, the selection signal generation circuit 52_GN outputs, as a selection signal, an input time width generated by adding the offset pulse width IN_{ofs} to the time length (effective pulse width) of any one of values 1 to 15 indicated by the serial signal SI1. As a result, in the second period, a selection signal having a pulse width equal to a sum of the effective pulse width and the offset pulse width IN_{ofs} is supplied to the word line WL1 as the input data x₁.

When the serial signal SI1 is 0, the selection signal generation circuit 52_GN does not output a high-level selection signal in either the first period or the second period. As a result, a low level is supplied to the word line WL1 as the input data x₁.

### Operation of AI MAC Arithmetic Unit

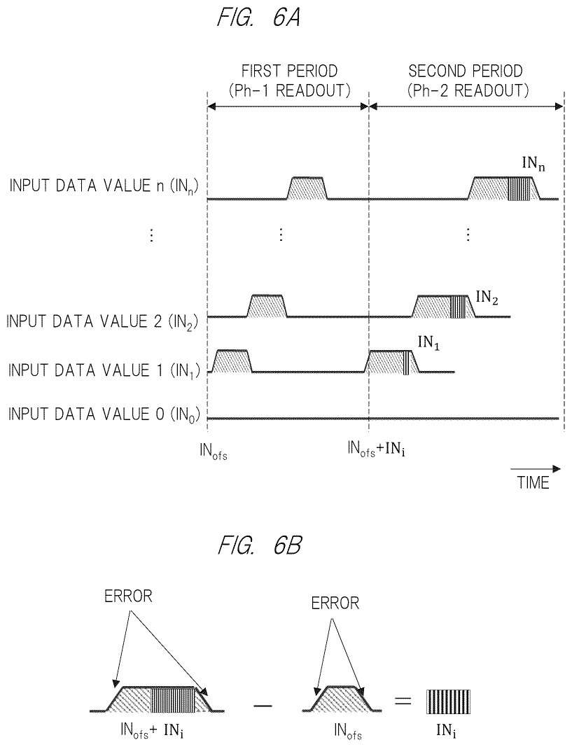

Next, an operation of the AI MAC arithmetic unit 50 illustrated in FIG. 2 will be described with reference to the drawings. FIGS. 6A and 6B are diagrams for explaining the operation of the AI MAC arithmetic unit according to the first embodiment. FIG. 6A illustrates charge amounts in a first period (Ph-1 readout) and a second period (Ph-2 readout) when a value of input data (for example, x₁) is 0 to n. FIG. 6B illustrates a subtraction operation between the first period and the second period. In FIG. 6A, for ease of explanation, values of input data 1 to n and values of stored data of memory cells to be calculated are assumed to be the same. Specifically, an impedance during conduction of the memory cells (the memory cell current Icell) is assumed to be the same among the values 1 to n. In addition, a case in which the first period exists before the second period will be described here; however, the first period may exist after the second period.

A case in which the input data x₁ is supplied to a word line (for example, the word line WL1 illustrated in FIG. 3) will be described. In this case, in the first period, a selection signal that is set to a high level for the offset pulse width IN_{ofs} is supplied to the word line WL1. The memory cell (for example, the memory cell M11 illustrated in FIG. 3) is brought into a conductive state by the high-level selection signal. At this point, an impedance of the memory cell M11 is a value determined according to the value of the stored data. As a result, in the first period, as illustrated in FIG. 6A, a charge amount corresponding to the offset pulse width IN_{ofs} (a charge amount determined by a product of IN_{ofs} and the memory cell current Icell) is discharged at the bit line (for example, the bit line BL1 illustrated in FIG. 3).

Next, in the second period, a selection signal that is set to a high level for an input time width (IN_{ofs}+IN₁), which is obtained by adding the offset pulse width IN_{ofs} to a pulse width (effective pulse width) IN₁ corresponding to the input data x₁, is supplied to the word line WL1. The memory cell M11 is brought into a conductive state by the high-level selection signal. As a result, in the second period, as illustrated in FIG. 6A, a charge amount corresponding to the input time width (IN_{ofs}+IN₁) (a charge amount determined by a product of IN_{ofs} +IN₁ and the memory cell current Icell) is discharged at the bit line BL1.

Although a case in which a value of the input data x₁ is 1 has been described, the same applies when the value is any one of 2 to n. Specifically, in the first period, a charge amount corresponding to the offset pulse width IN_{ofs} is discharged, and in the second period, a charge amount corresponding to an input time width (IN_{ofs}+INᵢ) determined by the value of the input data x₁ is discharged.

When the value of the input data x₁ is 0, a high-level selection signal is not supplied to the word line WL1 in either the first period or the second period. Therefore, as illustrated in FIG. 6A, charge is not discharged through the memory cell at the bit line BL1.

In the first embodiment, as illustrated in FIG. 6B, subtraction is performed between a charge amount discharged in the second period (a product of IN_{ofs}+INᵢ and Icell) and a charge amount discharged in the first period (a product of IN_{ofs} and Icell). By the subtraction, as illustrated in FIG. 6B, a charge amount corresponding to the offset pulse component (a product of IN_{ofs} and Icell) is subtracted, and errors generated at rising and falling edges of the word line (the errors α and β described in <Comparative Example>) are also subtracted (canceled). As a result, it is possible to obtain a charge amount corresponding to a value of the pure multiplication operation (a product of INᵢ and Icell). In addition, since a charge amount corresponding to the value of multiplication operation remains by the subtraction, it is possible to obtain a pulse width (effective pulse width) corresponding to the value of the input data without extending the pulse width according to the value of the input data, as described in <Comparative Example>. Accordingly, it is possible to achieve higher speed.

A signal corresponding to a charge amount determined by a product of the memory cell current Icell determined by stored data of the memory cell and the input time width (IN_{ofs}+INᵢ) is hereinafter also referred to as an input signal.

Similarly, a signal corresponding to a charge amount determined by a product of the memory cell current Icell determined by the stored data of the memory cell and the offset pulse width IN_{ofs} is hereinafter also referred to as an offset signal.

Further, according to the AI MAC arithmetic unit according to the first embodiment, it is possible to reduce a total pulse width of input data including the offset pulse width (IN_{ofs}), and it is possible to achieve higher speed. This will be described next with reference to the drawings.

### Reduction of Total Pulse Width

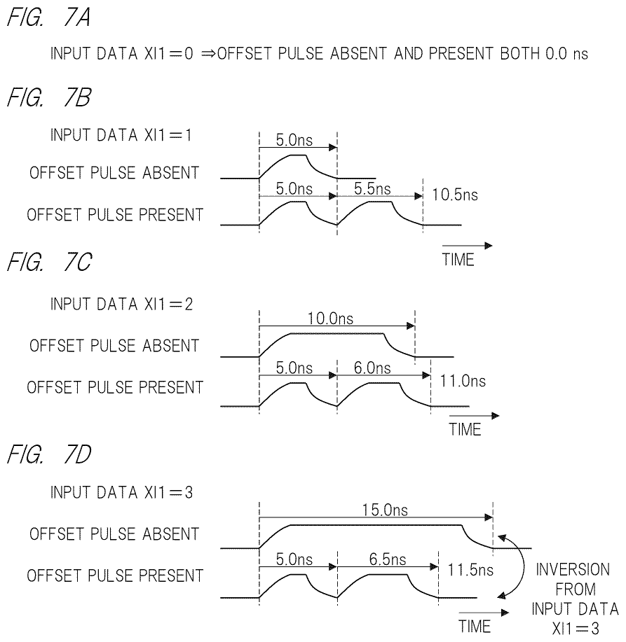

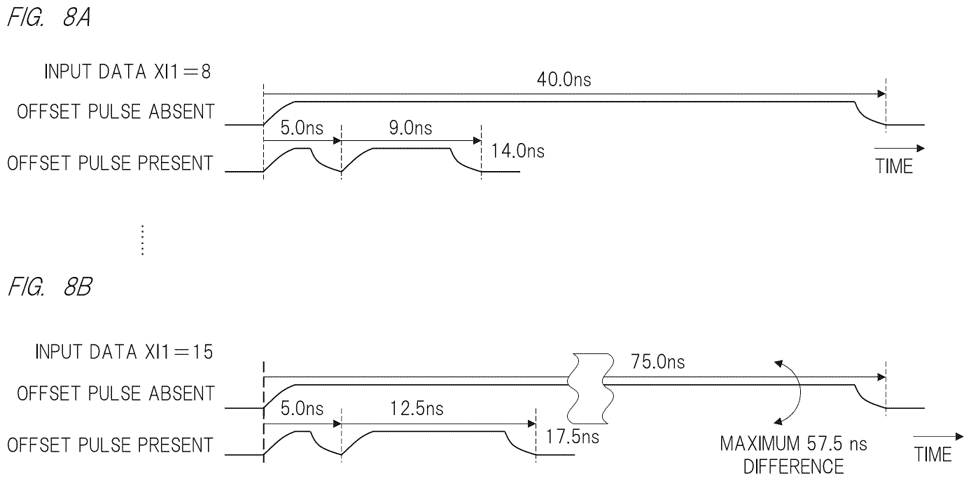

FIGS. 7A to 7D, 8A, and 8B are diagrams for explaining the AI MAC arithmetic unit according to the first embodiment. For ease of explanation, a case under the conditions described below will be explained here.

Specifically, the input data XI1 is 4-bit parallel data, and a value of the input data x₁ corresponding to the input data XI1 is converted into any one of 0 to 15. In addition, a pulse width of a high-level selection signal on the word line WL1, with which errors described with reference to FIG. 6 can be ignored, is set to 5 ns.

In the AI MAC arithmetic unit according to the first embodiment, 5 ns, which is the pulse width of the high-level selection signal with which the errors can be ignored, is set as the offset pulse width IN_{ofs}, and a minimum unit pulse width (effective pulse width) IN₁ of the input data x₁ is set to 0.5 ns. On the other hand, in the <Comparative Example>, when a value of the input data x₁ is 1, specifically, when the input data XI1=1, a pulse width of the high-level selection signal is the above-described 5 ns, and when the input data XI1=2 to 15, the pulse width of the high-level selection signal is 5 ns×2 to 15.

FIGS. 7A to 7D illustrate voltage waveforms on the word line WL1 when the input data XI1=0 to 3. In FIGS. 7B to 7D, a horizontal axis represents time, and a vertical axis represents a voltage of the word line. In addition, FIGS. 8A and 8B illustrate voltage waveforms on the word line WL1 when the input data XI1=8 and 15.

In FIGS. 7B to 7D and FIGS. 8A and 8B, “offset pulse absent” indicates voltage waveforms of the word line WL1 in the <Comparative Example>, and “offset pulse present” indicates voltage waveforms of the word line WL1 in the AI MAC arithmetic unit according to the first embodiment. In addition, although a voltage waveform is not illustrated in FIG. 7A, this indicates a case where the input data XI1 is 0, and therefore a pulse width of the high-level selection signal on the word line WL1 is 0 ns.

When the input data XI1=1, as illustrated in FIG. 7B, in the case where the offset pulse is absent (<Comparative Example>), a width of the selection signal is 5 ns. On the other hand, when the offset pulse is present, the selection signal has a total pulse width of 10.5 ns, which is a sum of the offset pulse width of 5 ns and an input time width corresponding to the value of the input data XI1 (an effective pulse width of 0.5 ns having a time length corresponding to the value of the input data).

Similarly, when the input data XI1=2, as illustrated in FIG. 7C, in the case where the offset pulse is absent, the width of the selection signal is 10.0 ns. On the other hand, when the offset pulse is present, the width of the selection signal is 11.0 ns.

However, when the input data XI1=3, as illustrated in FIG. 7D, the width of the selection signal is 15.0 ns when the offset pulse is absent, whereas the width of the selection signal is 11.5 ns when the offset pulse is present. Specifically, a period during which the word line WL1 is at a high level is reversed between the case where the offset pulse is absent and the case where the offset pulse is present, and the case where the offset pulse is present becomes shorter.

Thereafter, as the value of the input data XI1 increases, in the case where the offset pulse is absent, the high-level width of the selection signal increases in units of 5 ns, whereas in the case where the offset pulse is present, the high-level width of the selection signal increases in units of 0.5 ns. As a result, as illustrated in FIG. 8A, when the input data XI1=8, the width of the selection signal is 40.0 ns in the case where the offset pulse is absent, whereas the width of the selection signal is 14.0 ns in the case where the offset pulse is present. Further, when the input data XI1=15, which is the maximum value, as illustrated in FIG. 8B, the width of the selection signal is 75.0 ns in the case where the offset pulse is absent, whereas the width of the selection signal is 17.5 ns in the case where the offset pulse is present.

Specifically, a maximum difference of 57.5 ns occurs depending on whether the offset pulse is present. By reducing a time width during which the word line is at a high level, it is possible to achieve higher speed.

### Specific Configuration of AI MAC Arithmetic Unit

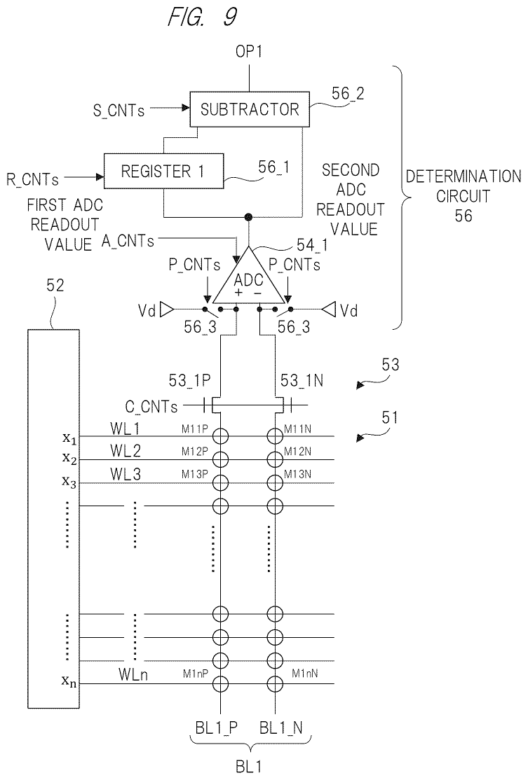

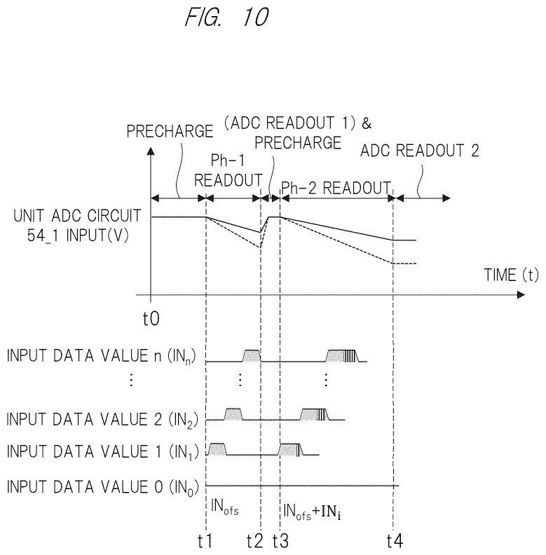

Next, a more specific configuration of the AI MAC arithmetic unit will be described. FIG. 9 is a circuit diagram illustrating a configuration of the AI MAC arithmetic unit according to the first embodiment. FIG. 10 is a waveform diagram for explaining an operation of the AI MAC arithmetic unit illustrated in FIG. 9.

In FIG. 9, portions mainly including the memory cell array 51, the row decoder 52, the column selector 53, and the AD conversion circuit 54 illustrated in FIG. 2 are depicted. FIG. 9 is similar to FIGS. 3 and 15, and more specifically illustrates, as a representative example, a portion corresponding to one bit line BL1 illustrated in FIGS. 3 and 15. Specifically, although in FIGS. 3 and 15, an input terminal of the unit AD conversion circuit 54_1 is one, more specifically, as illustrated in FIG. 9, the unit AD conversion circuit 54_1 includes a positive (+) input terminal and a negative (−) input terminal, and when conversion is instructed by a conversion control signal A_CNTs, converts a differential voltage between the positive (+) input terminal and the negative (−) input terminal into a digital signal.

The bit line BL1 is constituted by a pair of bit lines (a first bit line and a third bit line) BL1_P and BL1_N. The bit line BL1_P is connected to the positive (+) input terminal of the unit AD conversion circuit via a field-effect transistor (hereinafter also simply referred to as a transistor) 53_1P constituting the column selector 53, and the bit line BL1_N is connected to the negative (−) input terminal of the unit AD conversion circuit via a transistor 53_1N constituting the column selector 53. The field-effect transistors 53_1P and 53_1N are switch-controlled by a column selector control signal C_CNTs.

A plurality of memory cells (first memory cells) M11P to M1nP is connected to the bit line BL1_P, and a plurality of memory cells (third memory cells) M11N to M1nN is connected to the bit line BL1_N. As illustrated in FIG. 9, memory cells arranged in the same row, for example, the memory cells M11P and M11N, are connected to the word line WL1 arranged in the corresponding row. Other memory cells M12P to M1nP and M12N to M1nN are similarly connected such that memory cells arranged in the same row are connected to the word lines WL2 to WLn arranged in the corresponding rows. Input data x₁ to xₙ are supplied from the row decoder 52 to the word lines WL1 to WLn.

In FIG. 9, in order to avoid complication of the drawing, the memory cells M11P to M1nP and M11N to M1nN are illustrated by circles; however, specifically, as illustrated in FIGS. 3 and 15, each of the memory cells is constituted by a field-effect transistor FMOS including a selection gate connected to a word line arranged in a corresponding row, a floating gate, a drain connected to a corresponding bit line, and a source connected to the ground voltage Vs.

Two memory cells connected to the same word line, for example, M11P and M11N, are written with mutually related data, although not particularly limited. Specifically, inverted data with respect to the memory cell M11P is written in the memory cell M11N. For example, when binary data “1” is stored in the memory cell M11P, inverted binary data “0” is stored in the memory cell M11N. The unit AD conversion circuit 54_1 obtains a difference between a voltage based on stored data of the memory cell M11P supplied to the positive (+) input terminal and a voltage based on stored data of the memory cell M11N supplied to the negative (−) input terminal, and performs AD conversion on the obtained difference.

A precharge switch 56_3 that is switch-controlled by a precharge control signal P_CNT is connected between the positive (+) input terminal and the negative (−) input terminal of the unit AD conversion circuit 54_1 and a predetermined power supply voltage Vd having a predetermined potential with respect to the ground voltage Vs.

An output of the unit AD conversion circuit 54_1 is connected to a register 56_1 serving as a storage circuit and to a digital subtractor (arithmetic circuit) 56_2. When holding is instructed by a holding control signal R_CNTs, the register 56_1 holds an output of the unit AD conversion circuit 54_1 at that time and outputs the held output to the subtractor 56_2. When subtraction is instructed by a subtraction control signal S_CNTs, the subtractor 56_2 performs subtraction between an output of the unit AD conversion circuit 54_1 at that time and an output from the register 56_1, and outputs a subtraction result as a digital signal OP1. A value of the digital signal OP1 indicates a result of a multiply-accumulate operation between stored data of the memory cells M11P to M1nP and the input data x₁ to xₙ.

In FIG. 9, it can be regarded that the unit AD conversion circuit 54_1, the precharge switch 56_3, the register 56_1, and the subtractor 56_2 constitute a determination circuit that determines a result of the multiply-accumulate operation.

The precharge control signal P_CNTs, the column selector control signal C_CNTs, the holding control signal R_CNTs, the subtraction control signal S_CNTs, and the conversion control signal A_CNTs illustrated in FIG. 9 are generated by the control circuit 55 illustrated in FIG. 2.

### Specific Operation of AI MAC Arithmetic Unit

Next, a specific operation of the AI MAC arithmetic unit illustrated in FIG. 9 will be described with reference to FIGS. 9 and 10. FIG. 10 is similar to FIG. 6A. A difference from FIG. 6A is that, in FIG. 10, input waveforms of the unit AD conversion circuit 54_1 and timing of the AI MAC arithmetic unit are explicitly illustrated on an upper side of the drawing. In addition, FIG. 10 explicitly illustrates readout periods (ADC readout 1 and ADC readout 2) of the unit AD conversion circuit 54_1 and a precharge period, as compared with FIG. 6A.

At time t0, the transistors 53_1P and 53_1N are brought into a conductive state in accordance with an instruction of the column selector control signal C_CNTs, and the precharge switch 56_3 is brought into a conductive state in accordance with an instruction of the precharge control signal P_CNTs. As a result, during a period from time t0 to time t1, the bit lines BL1_P and BL1_N and input terminals of the unit AD conversion circuit 54_1 are precharged by a power supply voltage Vd supplied via the conductive transistors and the precharge switch.

In a first period from time t1 to time t2 (Ph-1 readout), the input data x₁ to xₙ are supplied from the row decoder 52 to the word lines WL1 to WLn. As described with reference to FIGS. 5 and 6A, in the first period, when input data is present, specifically, when a value of the input data is not 0 but is 1 to 15, the row decoder 52 supplies a high-level selection signal having the offset pulse width IN_{ofs} to the word lines as the input data x₁ to xₙ. In memory cells to which the high-level selection signal is supplied, a field-effect transistor FMOS constituting each memory cell becomes conductive with an impedance corresponding to the stored data. As a result, charges precharged in the bit lines BL1_P and BL1_N are discharged through one or more memory cells that are connected to the bit lines and are in a conductive state, and voltages of the bit lines BL1_P and BL1_N decrease as illustrated in FIG. 10. In FIG. 10, a solid line illustrates a voltage of the bit line BL1_P as an example, and a broken line illustrates a voltage of the bit line BL1_N as an example.

Next, in a period from time t2 to time t3, ADC readout 1 and precharge ((ADC readout 1) and precharge) are performed. Specifically, first, the transistors 53_1P and 53_1N are brought into a non-conductive state in accordance with an instruction of the column selector control signal C_CNTs. Thereafter, the unit AD conversion circuit 54_1 is operated in accordance with an instruction of the conversion control signal A_CNTs. When a conversion operation by the unit AD conversion circuit 54_1 is completed, the register 56_1 captures and holds a conversion result in accordance with an instruction of the holding control signal R_CNTs. As a result, ADC readout 1 by the determination circuit 56 is completed.

Thereafter, the transistors 53_1P and 53_1N are again brought into a conductive state in accordance with an instruction of the column selector control signal C_CNTs, and the precharge switch 56_3 is brought into a conductive state in accordance with an instruction of the precharge control signal P_CNTs. As a result, the bit lines BL1_P and BL1_N and the input terminals of the unit AD conversion circuit 54_1 are precharged again.

In a second period from time t3 to time t4 (Ph-2 readout), the input data x₁ to xₙ are supplied from the row decoder 52 to the word lines WL1 to WLn. As described with reference to FIGS. 5 and 6A, in the second period, when input data is present, specifically, when a value of the input data is not 0 but is 1 to 15, the row decoder 52 supplies, as the input data x₁ to xₙ, a selection signal that is set to a high level for an input time width (IN_{ofs}+INᵢ), which is obtained by adding the offset pulse width IN_{ofs} to an effective pulse width INᵢ corresponding to the input data, to the word lines. In memory cells to which the high-level selection signal is supplied, a field-effect transistor FMOS constituting each memory cell becomes conductive with an impedance corresponding to the stored data for a period determined by the input time width. As a result, charges precharged in the bit lines BL1_P and BL1_N are discharged through one or more memory cells that are connected to the bit lines and are in a conductive state, and voltages of the bit lines BL1_P and BL1_N decrease as illustrated in FIG. 10.

From time t4 onward, ADC readout 2 is performed. Similarly to ADC readout 1, first, the transistors 53_1P and 53_1N are brought into a non-conductive state in accordance with an instruction of the column selector control signal C_CNTs. Thereafter, the unit AD conversion circuit 54_1 is operated in accordance with an instruction of the conversion control signal A_CNTs. When the conversion operation by the unit AD conversion circuit 54_1 is completed, instead of operating the register 56_1, the subtractor 56_2 is operated in accordance with an instruction of the subtraction control signal S_CNTs. The subtractor 56_2 performs subtraction between a conversion result of ADC readout 1 stored in the register 56_1 and a current conversion result of the unit AD conversion circuit 54_1 (a conversion result of ADC readout 2). As a result, as described with reference to FIG. 6B, a digital signal based on a charge amount determined by the input time width and the stored data of the memory cell (ADC readout 2) is subtracted by a digital signal based on a charge amount determined by the offset pulse width and the stored data of the memory cell (ADC readout 1), and a result of the multiply-accumulate operation is output from the subtractor 56_2 as the digital signal OP1.

After the digital signal OP1 is output from the subtractor 56_2, the process returns to time t0, and precharge is performed again.

In the AI MAC arithmetic unit illustrated in FIG. 9, since the subtraction operation is performed digitally, it is also possible to suppress an increase in area due to analog elements such as capacitors.

Here, an example has been described in which the register 56_1 stores a digital signal based on a charge amount determined by the offset pulse width and the stored data of the memory cell; however, the present invention is not limited thereto. Specifically, a digital signal based on a charge amount determined by the input time width and the stored data of the memory cell may be stored in the register 56_1. In this case, the subtractor 56_2 performs a subtraction operation between a digital signal output from the unit AD conversion circuit 54_1 (a digital signal based on a charge amount determined by the offset pulse width and the stored data of the memory cell) and a digital signal from the register 56_1.

### Modification

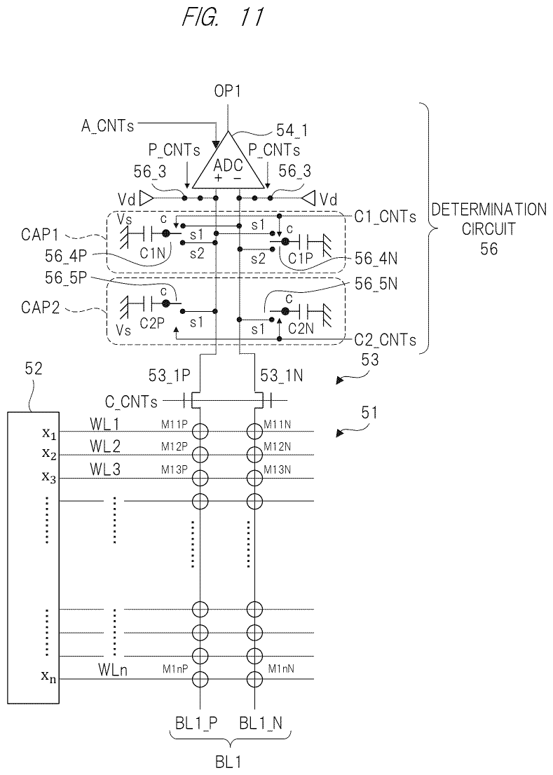

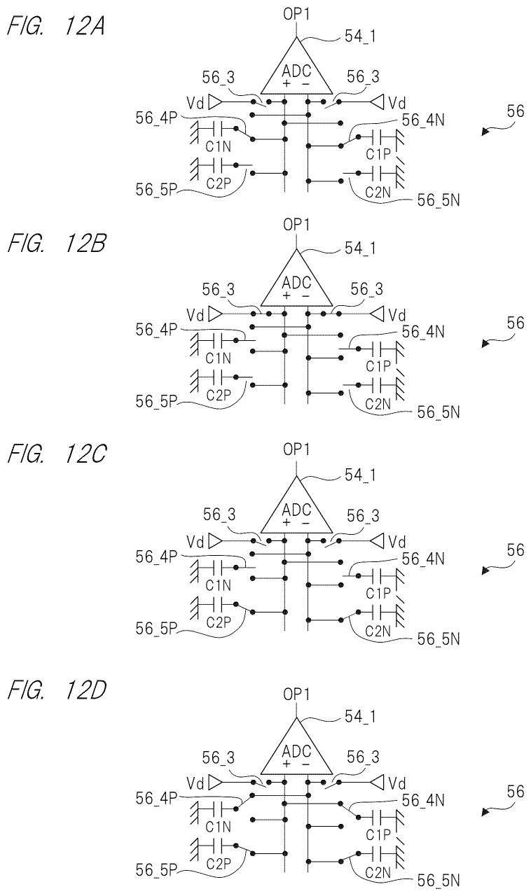

FIG. 11 is a circuit diagram illustrating a configuration of an AI MAC arithmetic unit according to a modification of the first embodiment. FIGS. 12A to 12D are diagrams for explaining an operation of the AI MAC arithmetic unit illustrated in FIG. 11.

FIG. 11 is similar to FIG. 9. A main difference is that, in FIG. 11, a configuration of the determination circuit 56 is modified as compared with FIG. 9. In FIG. 9, the subtraction operation is performed digitally, whereas in FIG. 11, the subtraction operation is performed in an analog manner.

In FIG. 11, configurations other than the determination circuit 56 are the same as those in FIG. 9, and therefore the determination circuit 56 illustrated in FIG. 11 will be mainly described here.

As illustrated in FIG. 11, the determination circuit 56 according to the modification includes the unit AD conversion circuit 54_1, an offset capacitance circuit CAP1, a data capacitance circuit CAP2, and the precharge switch 56_3. Here, since the unit AD conversion circuit 54_1 and the precharge switch 56_3 are the same as those in FIG. 9, detailed descriptions thereof are omitted.

The offset capacitance circuit CAP1 includes double-throw switches 56_4P and 56_4N and capacitances (first capacitive elements) C1N and C1P. The capacitance C1N is connected between the ground voltage Vs and a common terminal C of the double-throw switch 56_4P, and the capacitance C1P is connected between the ground voltage Vs and a common terminal C of the double-throw switch 56_4N. One terminal S1 of the double-throw switch 56_4P and an other terminal S2 of the double-throw switch 56_4N are connected to the bit line BL1_N via the transistor 53_1N. Further, an other terminal S2 of the double-throw switch 56_4P and one terminal S1 of the double-throw switch 56_4N are connected to the bit line BL1_P via the transistor 53_1P. The common terminals C of the double-throw switches 56_4P and 56_4N are connected to a terminal C1, a terminal C2, or an open terminal in accordance with an instruction of an offset capacitance control signal C1_CNTs. Here, the open terminal is a terminal in a floating state.

The data capacitance circuit CAP2 includes switches 56_5P and 56_5N and capacitances (second capacitive elements) C2N and C2P. The capacitance C2P is connected between the ground voltage Vs and a terminal C of the switch 56_5P, and the capacitance C2N is connected between the ground voltage Vs and a terminal C of the switch 56_5N. The terminal S1 of the switch 56_5P is connected to the bit line BL1_P via the transistor 53_1P, and the terminal S1 of the switch 56_5N is connected to the bit line BL1_N via the transistor 53_1N. The terminals C of the switches 56_5P and 56_5N are connected to a terminal C1 or an open terminal in a floating state in accordance with an instruction of a data capacitance control signal C2_CNTs. When the open terminal is included, the switches 56_5P and 56_5N may be regarded as double-throw switches.

### Operation of AI MAC Arithmetic Unit According to Modification

Next, an operation of the AI MAC arithmetic unit illustrated in FIG. 11 will be described with reference to FIGS. 11 and 12A to 12D.

The AI MAC arithmetic unit illustrated in FIG. 9 operates in the order of precharge, Ph-1 readout (first period), (ADC readout 1) and precharge, Ph-2 readout (second period), and ADC readout 2, as described with reference to FIG. 10. In contrast, the AI MAC arithmetic unit illustrated in FIG. 11 operates in the order of first precharge (precharge 1), Ph-1 readout (first period), second precharge (precharge 2), Ph-2readout, and charge sharing and ADC operation. A state of precharge 1 is illustrated in FIG. 11, and Ph-1 readout, precharge 2, Ph-2 readout, and charge sharing and ADC operation are illustrated in FIGS. 12A to 12D.

With reference to FIG. 11, precharge 1 will be described. In precharge 1, the transistors 53_1P and 53_1N constituting the column selector are brought into a conductive state, and the precharge switch 56_3 is also brought into a conductive state. As a result, the positive (+) and negative (−) input terminals of the unit AD conversion circuit 54_1 and the bit lines BL1_P and BL1_N are precharged by the power supply voltage Vd.

Next, with reference to FIGS. 10, 11, and 12A, Ph-1 readout (first period) will be described. In Ph-1 readout, as described for the first period (Ph-1 readout) from time t1 to time t2 in FIG. 10, for input data having values of 1 to 15, a high-level selection signal having the offset pulse width IN_{ofs} is supplied from the row decoder 52 as the input data x₁ to xₙ to the corresponding word lines WL1 to WLn. As a result, charges precharged in the bit lines BL1_P and BL1_N are discharged such that charge amounts determined by the offset pulse width IN_{ofs} and stored data of the memory cells are obtained, and voltages of the bit lines BL1_P and BL1_N become values determined by the offset pulse width IN_{ofs} and the stored data of the memory cells.

In Ph-1 readout (first period), in the determination circuit 56, as illustrated in FIG. 12A, the precharge switch 56_3 is brought into a non-conductive state, and in accordance with an instruction of the offset capacitance control signal C1_CNTs, the capacitances C1N and C1P are connected to the terminal S2 and further connected to the bit lines BL1_P and BL1_N via the transistors 53_1P and 53_1N. As a result, the capacitances C1N and C1P are charged by voltages of the bit lines BL1_P and BL1_N determined by the offset pulse width IN_{ofs} and the stored data of the memory cells.

Following Ph-1 readout, precharge 2 is executed. In precharge 2, as illustrated in FIG. 12B, in accordance with an instruction of the offset capacitance control signal C1_CNTs, the capacitances C1N and C1P are connected to an open terminal, and the precharge switch 56_3 is brought into a conductive state. As a result, similarly to precharge 1, the positive (+) and negative (−) input terminals of the unit AD conversion circuit 54_1 and the bit lines BL1_P and BL1_N via the transistors 53_1P and 53_1N are precharged by the power supply voltage Vd.

Subsequently, Ph-2 readout (second period) is executed. With reference to FIGS. 10, 11, and 12C, Ph-2 readout (second period) will be described. In Ph-2 readout, as described for the second period (Ph-2 readout) from time t3 to time t4 in FIG. 10, for input data having values of 1 to 15, a selection signal that is set to a high level for an input time width (IN_{ofs}+INᵢ), which is obtained by adding the offset pulse width IN_{ofs} to an effective pulse width INᵢ corresponding to the input data, is supplied from the row decoder 52 as the input data x₁ to xₙ to the corresponding word lines WL1 to WLn. As a result, charges precharged in the bit lines BL1_P and BL1_N are discharged such that charge amounts determined by the input time width (IN_{ofs}+INᵢ) and the stored data of the memory cells are obtained, and voltages of the bit lines BL1_P and BL1_N become values determined by the input time width (IN_{ofs}+INᵢ) and the stored data of the memory cells.

Further, in Ph-2 readout (second period), in the determination circuit 56, as illustrated in FIG. 12C, the precharge switch 56_3 is brought into a non-conductive state, and in accordance with an instruction of the data capacitance control signal C2_CNTs, the capacitances C2P and C2N are connected to the bit lines BL1_P and BL1_N via the transistors 53_1P and 53_1N. As a result, the capacitances C2P and C2N are charged by voltages of the bit lines BL1_P and BL1_N determined by the input time width (IN_{ofs}+INᵢ) and the stored data of the memory cells.

Next, charge sharing and ADC operation are executed. In this charge sharing and ADC operation, the transistors 53_1P and 53_1N are brought into a non-conductive state, and as illustrated in FIG. 12D, in accordance with an instruction of the offset capacitance control signal C1_CNTs, the capacitances C1N and C1P are connected to the negative (−) and positive (+) input terminals of the unit AD conversion circuit. At this time, as illustrated in FIG. 12D, the capacitances C2N and C2P are also connected to the negative (−) and positive (+) input terminals of the unit AD conversion circuit. Specifically, the capacitances C1N and C2N are connected to the negative electrode (−) of the unit AD conversion circuit, and the capacitances C1P and C2P are connected to the positive electrode (+) of the unit AD conversion circuit.

As a result, charge sharing (charge redistribution) is performed between the capacitances C1N and C2N in such a manner that subtraction of stored charge amounts is performed, and charge sharing (charge redistribution) is also performed between the capacitances C1P and C2P in such a manner that subtraction of stored charge amounts is performed. Specifically, an operation of subtracting a charge amount determined by the offset pulse width IN_{ofs} and the stored data of the memory cell from a charge amount determined by the input time width (IN_{ofs}+INᵢ) and the stored data of the memory cell is executed in an analog manner.

After subtraction of the charge amounts is performed, the unit AD conversion circuit 54_1 converts a voltage difference between the negative (−) and positive (+) input terminals into a digital signal and outputs the digital signal as the digital signal OP1.

According to the AI MAC arithmetic unit according to the modification, since subtraction is performed between charge amounts without conversion into digital signals, it is possible to accurately eliminate errors (α and β) described with reference to FIG. 18.

In the first embodiment, an example has been described in which the row decoder 52 supplies the input data x₁ to xₙ to the word lines WL1 to WLn in a time-series manner as illustrated in FIG. 10; however, the present invention is not limited thereto. Specifically, the row decoder 52 may supply the input data x₁ to xₙ to the word lines WL1 to WLn substantially simultaneously. By supplying the input data substantially simultaneously, it is possible to shorten the first period and the second period, and it is possible to achieve higher speed.

### Second Embodiment

In the first embodiment, a charge amount corresponding to the offset pulse width (IN_{ofs}) and a charge amount corresponding to the input time width (IN_{ofs}+INᵢ) are read out in mutually different first period and second period, and a result of a multiply-accumulate operation is obtained by performing subtraction digitally or analogically. In contrast, in the second embodiment, a configuration is provided in which a charge amount corresponding to the offset pulse width (IN_{ofs}) and a charge amount corresponding to the input time width (IN_{ofs}+INᵢ) are read out substantially simultaneously.

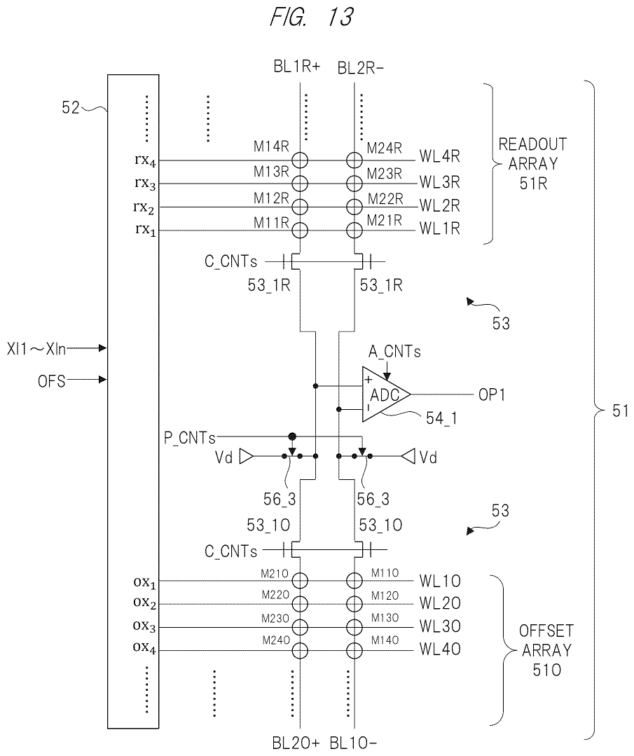

FIG. 13 is a circuit diagram illustrating a configuration of the AI MAC arithmetic unit according to the second embodiment. FIG. 13 illustrates the memory cell array 51 constituting the AI MAC arithmetic unit, the row decoder 52, the unit AD conversion circuit 54_1, and transistors constituting the column selector.

The memory cell array 51 is constituted by a readout array 51R and an offset array 510. Each of the readout array 51R and the offset array 510 includes a plurality of memory cells arranged in a matrix, word lines arranged in respective rows, and bit lines arranged in respective columns. In FIG. 13, as representative bit lines arranged in the arrays, two bit lines BL1R+ and BL2R− arranged in the readout array 51R and two bit lines BL10+ and BL20− arranged in the offset array 510 are explicitly illustrated. Similarly, as representative word lines arranged in the arrays, four word lines WL1R to WL4R arranged in the readout array 51R and four word lines WL10 to WL40 arranged in the offset array 510 are explicitly illustrated.

In FIG. 13, the memory cells are illustrated by circles; however, as illustrated in FIGS. 3 and 15, each memory cell is constituted by a field-effect transistor FMOS connected to a corresponding word line and a corresponding bit line. As representative memory cells arranged in the readout array 51R, the memory cells M11R to M14R and M21R to M24R connected to the word lines WL1R to WL4R and the bit lines BL1R+ and BL2R− are illustrated. As representative memory cells arranged in the offset array 510, the memory cells M110 to M140 and M210 to M240 connected to the word lines WL10 to WL40 and the bit lines BL10− and BL20+ are illustrated.

The bit lines BL1R+ and BL2R− are connected to the positive (+) and negative (−) input terminals of the unit AD conversion circuit 54_1 via the transistor 53_1R constituting the column selector 53. Similarly, the bit lines BL10− and BL20+ are connected to the positive (+) and negative (−) input terminals of the unit AD conversion circuit 54_1 via the transistor 53_10 constituting the column selector 53.

The positive (+) and negative (−) input terminals of the unit AD conversion circuit 54_1 are connected to the power supply voltage Vd via the precharge switch 56_3.

Based on the input data XI1 to XIn and the offset pulse signal OFS, the row decoder 52 generates readout input data rx₁ to rxₙ (in FIG. 13, readout input data rx₁ to rx₄) and supplies the readout input data to the word lines arranged in the readout array 51R (in FIG. 13, the word lines WL1R to WL4R). The row decoder 52 also generates offset input data ox₁ to oxₙ (in FIG. 13, offset input data ox₁ to ox₄) based on the input data XI1 to XIn and the offset pulse signal OFS and supplies the offset input data to the word lines in the offset array 510 (in FIG. 13, the word lines WL10 to WL40).

The bit line BL1R+ can be regarded as a first bit line, and the bit line BL10− can be regarded as a second bit line. The word lines WL1R to WL4R can be regarded as first word lines, and the word lines WL10 to WL40 can be regarded as second word lines. In this case, the memory cells M11R to M14R can be regarded as first memory cells, and the memory cells M110 to M140 can be regarded as second memory cells.

### Operation of AI MAC Arithmetic Unit

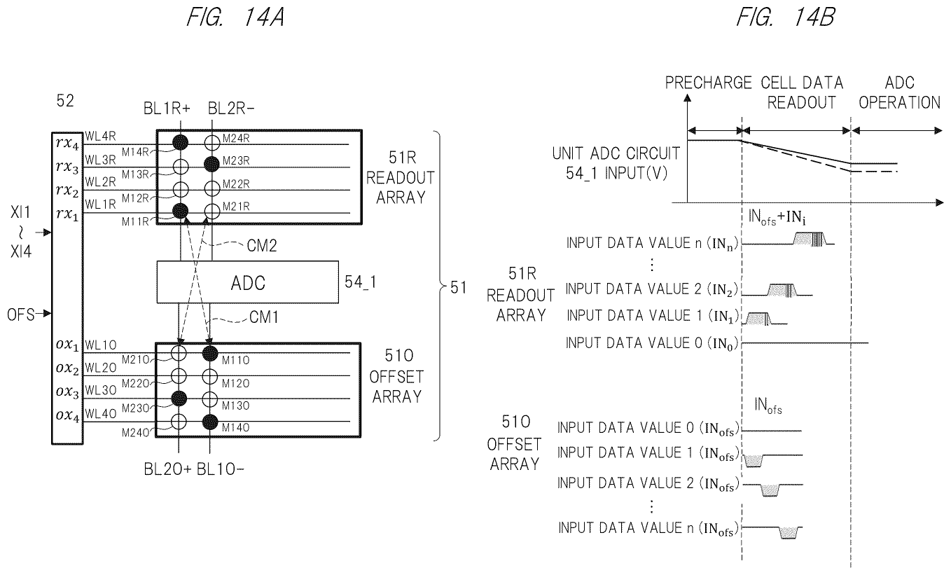

Next, the operation of the AI MAC arithmetic unit according to the second embodiment will be described with reference to the drawings. FIGS. 14A and 14B are diagrams for explaining the operation of the AI MAC arithmetic unit according to the second embodiment. Here, FIG. 14A is a block diagram illustrating a main part of the AI MAC arithmetic unit illustrated in FIG. 13, and FIG. 14B is a waveform diagram illustrating the operation of the AI MAC arithmetic unit.

In FIG. 14A, reference signs CM1 and CM2 indicate corresponding relationships between memory cells in the readout array 51R and memory cells in the offset array 510. The same data are written into memory cells that are in a mutually corresponding relationship. Specifically, as indicated by the corresponding relationship CM1, the memory cells opposing the memory cells M11R to M14R connected to the bit line BL1R+ are the memory cells M110 to M140 connected to the bit line BL10−. Similarly, as indicated by the corresponding relationship CM2, the memory cells opposing the memory cells M21R to M24R connected to the bit line BL2R− are the memory cells M210 to M240 connected to the bit line BL20+.

For example, in the memory cells M11R and M110 indicated by the corresponding relationship CM1, the same data as those written into the memory cell M11R are written into the corresponding memory cell M110. Similarly, in the memory cells M21R and M210 indicated by the corresponding relationship CM2, the same data as those written into the memory cell M21R are written into the corresponding memory cell M210. The same applies to the other memory cells.

When the memory cell M11R and the memory cell M110 store the same data and the memory cell M21R and the memory cell M210 store the same data, a sum (multiply-accumulate result) between a product relating to the memory cell M11R and a product relating to the memory cell M21R is calculated, as illustrated in the following equation. In the following equation, M11R, M21R, M110, and M210 indicate impedance values determined by the stored data of the memory cells M11R, M21R, M110, and M210, respectively.

The charge amount accumulated at the positive electrode (+) of the unit AD conversion circuit 54_1 is M11R×(IN₁+IN_{ofs})+M210×(IN_{ofs}). At this point, the charge amount accumulated at the negative electrode (−) of the unit AD conversion circuit 54_1 is M21R×(IN₁+IN_{ofs})+M110×(IN_{ofs}).

In the unit AD conversion circuit 54_1, subtraction between the charge amount at the positive electrode (+) and the charge amount at the negative electrode (−) is performed. Accordingly, the output of the unit AD conversion circuit 54_1 becomes (M11R×(IN₁+IN_{ofs})+M210×(IN_{ofs}))−(M21R×(IN₁+IN_{ofs})+M110×(IN_{ofs}))=M11R×(IN₁+IN_{ofs})+M21R×(IN_{ofs}) −M21R×(IN₁+IN_{ofs})+M11R×(IN_{ofs})=M11R×(IN₁)−M21R×(IN₁). Specifically, a sum between a product relating to the memory cell M11R (M11R×(IN₁)) and a product relating to the memory cell M21R (M21R×(IN₁)) is output.

### Operation

When the transistors 53_1R and 53_10 (FIG. 13) are brought into a conductive state and the precharge switch 56_3 (FIG. 13) is brought into a conductive state, in a period indicated as precharge in FIG. 14B, the positive (+) and negative (−) input terminals of the unit AD conversion circuit 54_1 and the bit lines BL1R+, BL2R−, BL10−, and BL20+ are precharged by the power supply voltage Vd.

In a period indicated as cell data readout in FIG. 14B, when values of the input data XI1 to XI4 are not 0, the row decoder 52 supplies, as the readout input data rx₁ to rx₄, selection signals each having a high-level period corresponding to an input time width (IN_{ofs}+INᵢ) to the word lines WL1R to WL4R, as illustrated in FIG. 14B. At the same time, the row decoder 52 supplies, as the offset input data ox₁ to ox₄, selection signals each having a high-level period corresponding to the offset pulse width (IN_{ofs}) to the word lines WL10 to WL40.

As a result, in the readout array 51R, charges precharged in advance on the bit lines BL1R+ and BL2R− are discharged and become charge amounts determined by a product of the input time width (IN_{ofs}+INᵢ) and stored data written in the memory cells. Specifically, total charge amounts of the bit lines BL1R+ and BL2R− respectively represent results of the multiply-accumulate operation. Similarly, in the offset array 510, charges precharged in advance on the bit lines BL20+ and BL10− are discharged and become charge amounts determined by a product of the offset pulse width (IN_{ofs}) and stored data written in the memory cells. Specifically, total charge amounts of the bit lines BL20+ and BL10− respectively also represent results of the multiply-accumulate operation.

In the memory cells of the offset array 510, as described above, data having opposite polarity are written with respect to the corresponding memory cells in the readout array 51R, and therefore the charge amounts become negative, as illustrated in FIG. 14B. Accordingly, as illustrated in FIG. 13, by bringing the transistors 53_1R and 53_10 constituting the column selector into a conductive state, addition is performed between the total charge amount of the bit line BL1R+ and the total charge amount of the bit line BL20+. Similarly, by bringing the transistors 53_1R and 53_10 constituting the column selector into a conductive state, addition is performed between the total charge amount of the bit line BL2R− and the total charge amount of the bit line BL10−. The total charge amount of the bit lines BL1R+ and BL20+ obtained by the addition and the total charge amount of the bit lines BL2R− and BL10− obtained by the addition are subtracted by the unit AD conversion circuit 54_1.

By the addition of the total charge amounts, a difference is obtained between a total charge amount determined by a multiply-accumulate of stored data of the memory cells M11R to M14R and the input time width and a total charge amount determined by a multiply-accumulate of stored data of the memory cells M110 to M140 and the offset pulse width, and a voltage at the positive (+) input terminal of the unit AD conversion circuit 54_1 is determined based on this difference. Similarly, a difference is obtained between a total charge amount determined by a multiply-accumulate of stored data of the memory cells M21R to M24R and the input time width and a total charge amount determined by a multiply-accumulate of stored data of the memory cells M210 to M240 and the offset pulse width, and a voltage at the negative (−) input terminal of the unit AD conversion circuit 54_1 is determined based on this difference. Since the unit AD conversion circuit 54_1 converts a difference between the positive (+) and negative (−) input terminals, a difference between the two total charge amounts is converted.

As a result, the total charge amount based on the multiply-accumulate of the memory cells M11R to M14R is subtracted by the total charge amount based on the multiply-accumulate of the memory cells M110 to M140, and a result of the multiply-accumulate operation of the memory cells M11R to M14R is obtained. Also, the total charge amount based on the multiply-accumulate of the memory cells M21R to M24R is subtracted by the total charge amount based on the multiply-accumulate of the memory cells M210 to M240, and a result of the multiply-accumulate operation of the memory cells M21R to M24R is obtained. From the unit AD conversion circuit 54_1, a result of the multiply-accumulate operation between the memory cells M11R to M14R and the memory cells M21R to M24R is obtained.

Specifically, after the subtraction is performed, the transistors 53_1R and 53_10 constituting the column selector are brought into a non-conductive state, and in a period indicated as ADC operation in FIG. 14B, the unit AD conversion circuit 54_1 converts a voltage between the positive (+) and negative (−) terminals into a digital signal, whereby a digital signal OP1 corresponding to a result of the multiply-accumulate operation of the memory cells M11R to M14R and M21R to M24R is obtained.

According to the AI MAC arithmetic unit of the second embodiment, it is possible to achieve higher speed. It is also possible to reduce signal loss during subtraction.

In FIG. 13, a configuration may be adopted in which the bit line BL2R− and the memory cells M21R to M24R connected thereto and the bit line BL20+ and the memory cells M210 to M240 connected thereto are omitted. Specifically, a so-called open-bit configuration may be adopted in which the bit line BL1R+ and the bit line BL10− are arranged on left and right sides of the unit AD conversion circuit 54_1. In this case, a total charge amount based on the multiply-accumulate of the memory cells M11R to M14R is subtracted by a total charge amount based on the multiply-accumulate of the memory cells M110 to M140 by the unit AD conversion circuit 54_1, and a result of the multiply-accumulate operation of the memory cells M11R to M14R is obtained. Even in this case, it is possible to read out a charge amount corresponding to the offset pulse width (IN_{ofs}) and a charge amount corresponding to the input time width (IN_{ofs}+INᵢ) substantially simultaneously, and it is possible to achieve higher speed. In this case, it is not necessary to write data having opposite polarity into the memory cells M110 to M140.

In the second embodiment as well, an example has been described in which the row decoder 52 supplies the input data rx₁ to rx₄ and ox₁ to ox₄ to the word lines WL1R to WL4R and WL10 to WL40 in a time-series manner as illustrated in FIG. 14. However, the present disclosure is not limited thereto. Specifically, the row decoder 52 may supply the input data rx₁ to rx₄ and ox₁ to ox₄ to the word lines WL1R to WL4R and WL10 to WL40 substantially simultaneously. By supplying the input data substantially simultaneously, it is possible to shorten a period of cell data readout illustrated in FIG. 14A, and it is possible to achieve further speed enhancement.

An example of effects of reducing power consumption and increasing speed of the AI MAC arithmetic unit according to the embodiment will be described numerically as follows. Here, as conditions, in addition to the conditions described in <<Reduction of Total Pulse Width>>, the number of the input data XIn is 64 (specifically, the number of the word lines WL is 64), a precharge time is 2 ns, a bit-line current of the memory cell is 10 μA, and a bit-line voltage is 0.1 V. It is also assumed that an average value of the input data XI is 8.

In the above-described <Comparative Example>, an operation time excluding the ADC operation is 5.0 ns/1 input×8 (average value of the input data)×64 WL=2560 ns. Further, power consumption is 2560 ns×0.1 V×10 μA=2560 fJ.

In contrast, in the AI MAC arithmetic unit according to the first embodiment, an operation time in the first period is 5.0 ns×64 WL=320 ns, and an operation time in the second period is (5.0 ns+0.5 ns/1 input×8 (average value of the input data))×64 WL=576 ns. Therefore, the operation time excluding the ADC operation is 320 ns+576 ns=896 ns. Further, power consumption is 896 ns×0.1 V×10 μA=896 fJ. It is possible to shorten the operation time by approximately 65%, and it is possible to achieve approximately 65% speed enhancement. It is also possible to reduce the power consumption from 2560 fJ to 896 fJ.

Further, according to the embodiment, since errors (α, β in FIG. 18) generated by rising and falling of the word lines and the like are cancelled, it is possible to improve inference accuracy during an inference operation.

In the embodiment, a flash memory cell has been described as an example of the memory cell; however, the present disclosure is not limited thereto. For example, the memory cell may be a volatile memory cell instead of an electrically rewritable nonvolatile memory cell.

In the foregoing, the invention made by the inventors of the present application has been concretely described on the basis of the embodiments. However, it is needless to say that the present invention is not limited to the foregoing embodiments, and various modifications and alterations can be made within the scope of the present invention.

What is claimed is:

1. A semiconductor device comprising:
a plurality of first memory cells connected to a first bit line and to a plurality of first word lines;
a determination circuit connected to the first bit line; and
an input circuit to which input data corresponding to the first word lines are supplied, the input circuit being configured to supply, to the corresponding first word lines, selection signals each having an input time width obtained by adding an offset pulse width having a predetermined time width to an effective pulse width having a time width corresponding to a value of the input data,
wherein the first memory cells discharge charge amounts determined by stored data stored therein and the input time width, and
wherein the determination circuit determines a difference between a charge amount discharged by the first memory cells and a charge amount based on the offset pulse width as a product of the value of the input data and the stored data, and outputs a multiply-accumulate of the plurality of first memory cells.

2. The semiconductor device according to claim 1,
wherein the input circuit supplies, in a first period, a selection signal having the offset pulse width to the first word lines, and supplies, in a second period different from the first period, a selection signal having the input time width to the first word lines, and
wherein an offset signal corresponding to a charge amount determined by the stored data and the offset pulse width in the first period is supplied to the determination circuit, and an input signal corresponding to a charge amount determined by the stored data and the input time width in the second period is supplied to the determination circuit.

3. The semiconductor device according to claim 1, further comprising
a second bit line different from the first bit line and a plurality of second memory cells connected to a plurality of second word lines different from the first word lines,
wherein the second bit line is connected to the determination circuit,
wherein the input circuit supplies a selection signal having the offset pulse width to the second word lines, and the second memory cells discharge charge amounts determined by stored data stored in the second memory cells and the offset pulse width, and
wherein the determination circuit determines a difference between a charge amount discharged by the first memory cells and a charge amount discharged by the second memory cells as a product of the value of the input data and the stored data of the first memory cells.

4. The semiconductor device according to claim 2,
wherein the determination circuit includes an AD conversion circuit, a storage circuit, and an arithmetic circuit,
wherein the AD conversion circuit converts the offset signal and the input signal into digital signals,
wherein the storage circuit stores either a digital signal corresponding to the offset signal converted by the AD conversion circuit or a digital signal corresponding to the input signal converted by the AD conversion circuit,
wherein the arithmetic circuit performs subtraction between a digital signal stored in the storage circuit and a digital signal not stored in the storage circuit, and
wherein the determination circuit determines a digital signal obtained by the subtraction performed by the arithmetic circuit as a product of the value of the input data and the stored data.

5. The semiconductor device according to claim 2,
wherein the determination circuit includes an AD conversion circuit, a first capacitive element, and a second capacitive element,
wherein the first capacitive element is charged with the charge amount determined by the stored data and the offset pulse width, and the second capacitive element is charged with the charge amount determined by the stored data and the input time width,
wherein the first capacitive element and the second capacitive element are connected so as to perform charge sharing between the first capacitive element and the second capacitive element,
wherein the AD conversion circuit converts an analog signal corresponding to the charge amount determined by the charge sharing into a digital signal, and
wherein the determination circuit determines a digital signal obtained by conversion by the AD conversion circuit as a product of the value of the input data and the stored data.

6. The semiconductor device according to claim 1, further comprising
a third bit line and a plurality of third memory cells connected to the plurality of first word lines,
wherein data related to the stored data stored in the plurality of first memory cells are stored in the plurality of third memory cells, and
wherein the determination circuit includes an AD conversion circuit having a positive input terminal and a negative input terminal connected to the first bit line and the third bit line.
